(19) United States
(12) Patent Application Publication
(10) Pub. No.: US 2021/0134592 A1
(43) Pub. Date: May 6, 2021

(54) SURFACE ENCASING MATERIAL LAYER

(71) Applicant: Applied Materials, Inc., Santa Clara, CA (US)

(72) Inventors: Madhu Santosh Kumar Mutyala, Santa Clara, CA (US); Sanjay Kamath, Fremont, CA (US); Deenesh Padhi, Sunnyvale, CA (US)

(73) Assignee: Applied Materials, inc., Santa Clara, CA (US)

(21) Appl. No.: 17/081,773

(22) Filed: Oct. 27, 2020

Related U.S. Application Data
(60) Provisional application No. 62/929,291, filed on Nov. 1, 2019.

(51) Int. Cl. H01L 21/02; H01J 37/32; C23C 16/52; C23C 16/50; C23C 16/40

(52) U.S. Cl. CPC H01L 21/02274; H01L 21/02164; H01L 21/02208; H01J 37/32449; H01J 2237/182; C23C 16/52; C23C 16/50; C23C 16/401; H01J 2237/3321; H01J 37/32816

(57) ABSTRACT

Exemplary deposition methods may include delivering a silicon-containing precursor and a carrier precursor to a processing region of a semiconductor processing chamber. The methods may include forming a plasma of the silicon-containing precursor and the carrier precursor within the processing region of the semiconductor processing chamber. The methods may include depositing a first amount of a silicon-containing material on a substrate disposed within the processing region of the semiconductor processing chamber. The depositing may occur at a first chamber pressure. The methods may include adjusting the first chamber pressure to a second chamber pressure less than the first chamber pressure. The methods may include depositing a second amount of the silicon-containing material on the first amount of the silicon-containing material.

### CROSS REFERENCES TO RELATED APPLICATIONS

This application claims the benefit of priority to U.S. Patent Application No. 62/929,291 filed Nov. 1, 2019, the contents of which are hereby incorporated by reference in their entirety for all purposes.

### TECHNICAL FIELD

The present technology relates to semiconductor deposition processes. More specifically, the present technology relates to methods of depositing materials with reduced stress effects.

### BACKGROUND

Integrated circuits are made possible by processes which produce intricately patterned material layers on substrate surfaces. Producing patterned material on a substrate requires controlled methods of formation and removal of exposed material. Material properties of films produced may contribute to substrate effects, which may cause wafer bowing or other challenges during processing.

Thus, there is a need for improved systems and methods that can be used to produce high quality devices and structures. These and other needs are addressed by the present technology.

### SUMMARY

Exemplary deposition methods may include delivering a silicon-containing precursor and a carrier precursor to a processing region of a semiconductor processing chamber. The methods may include forming a plasma of the silicon-containing precursor and the carrier precursor within the processing region of the semiconductor processing chamber. The methods may include depositing a first amount of a silicon-containing material on a substrate disposed within the processing region of the semiconductor processing chamber. The depositing may occur at a first chamber pressure. The methods may include adjusting the first chamber pressure to a second chamber pressure less than the first chamber pressure. The methods may include depositing a second amount of the silicon-containing material on the first amount of the silicon-containing material.

In some embodiments, the silicon-containing precursor is a silicon-and-oxygen-containing precursor, and the silicon-containing material may be or include silicon oxide. The first chamber pressure may be less than or about 20 Torr, and the second chamber pressure may be less than or about 10 Torr. A substrate temperature may be maintained above or about 300° C. while depositing the first amount of the silicon-containing material and the second amount of the silicon-containing material. The carrier precursor may be or include argon. The methods may include increasing a volumetric flow rate of the carrier precursor while adjusting the first chamber pressure to the second chamber pressure. The second amount of the silicon-containing material may be characterized by a greater density than the first amount of the silicon-containing material. The silicon-containing precursor may be or include tetraethyl orthosilicate. The second amount of the silicon-containing material may be characterized by a thickness of less than or about 100 nm.

Some embodiments of the present technology may encompass deposition methods. The methods may include delivering a silicon-containing precursor and a carrier precursor to a processing region of a semiconductor processing chamber. The methods may include forming a plasma of the silicon-containing precursor and the carrier precursor within the processing region of the semiconductor processing chamber. The methods may include depositing a first amount of a silicon-containing material on a substrate disposed within the processing region of the semiconductor processing chamber. The depositing may occur at a first chamber pressure. The methods may include adjusting the carrier precursor from a first volumetric flow rate to a second volumetric flow rate greater than the first volumetric flow rate. The methods may include depositing a second amount of the silicon-containing material on the first amount of the silicon-containing material.

In some embodiments, the silicon-containing precursor may be a silicon-and-oxygen-containing precursor. the silicon-containing material may be or include silicon oxide. The second volumetric flow rate may be more than 50% greater than the first volumetric flow rate. The methods may include adjusting the first chamber pressure to a second chamber pressure less than the first chamber pressure while adjusting the carrier precursor from the first volumetric flow rate to the second volumetric flow rate. The first chamber pressure may be less than or about 15 Torr, and the second chamber pressure may be less than or about 7 Torr. The second amount of the silicon-containing material may be characterized by a thickness of less than or about 100 nm. The second amount of the silicon-containing material may be characterized by a compressive stress greater than or about a compressive stress associated with the first amount of the silicon-containing material.

The present technology may also encompass deposition methods. The methods may include delivering a silicon-and-oxygen-containing precursor and a carrier precursor to a processing region of a semiconductor processing chamber. The methods may include forming a plasma of the silicon-and-oxygen-containing precursor and the carrier precursor within the processing region of the semiconductor processing chamber. The methods may include depositing a first amount of a silicon-and-oxygen-containing material on a substrate disposed within the processing region of the semiconductor processing chamber. The depositing may occur at a first chamber pressure. The methods may include adjusting the first chamber pressure to a second chamber pressure less than the first chamber pressure. The methods may include, while adjusting chamber pressure, increasing a volumetric flow rate of the carrier precursor. The methods may include depositing a second amount of the silicon-and-oxygen-containing material on the first amount of the silicon-and-oxygen-containing material.

In some embodiments, the first chamber pressure may be less than or about 20 Torr, and the second chamber pressure may be less than or about 10 Torr. The silicon-and-oxygen-containing precursor may be or include tetraethyl orthosilicate, and the carrier precursor may be or include argon. The first amount of the silicon-and-oxygen-containing material may be deposited over a first period of time, and the second amount of the silicon-and-oxygen-containing material may be deposited over a second period of time less than the first period of time.

Such technology may provide numerous benefits over conventional systems and techniques. For example, the processes may produce films characterized by reduced film shrinking. Additionally, the operations of embodiments of the present technology may produce films that maintain a controlled compressive stress when exposed to atmosphere. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a deposition method according to some embodiments of the present technology.

FIGS. 3A-3C show a schematic views of a substrate during deposition operations according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During semiconductor fabrication, structures may be produced on a substrate utilizing a variety of deposition and etching operations. Silicon oxide and other silicon-containing materials are routinely formed in a number of operations for developing semiconductor substrates. Silicon oxide, as one example, may be deposited in a number of processes including chemical vapor deposition and plasma deposition. Silicon oxide deposited or formed in some processes may be characterized by an amount of hydrogen and/or carbon incorporated in the film, which may have been included in the precursors, such as silane or tetraethyl orthosilicate. During subsequent processing, the silicon oxide film may be exposed to high temperatures, such as during subsequent annealing, for example. This high temperature exposure may cause an amount of outgassing of residual materials incorporated during the deposition process, which may cause the film to shrink.

To limit shrinking effects, some conventional technologies may produce denser oxide films, however, the denser films may exhibit increased internal stress. Silicon oxide may be characterized by a compressive stress, and when shrinking or densifying, the compressive stress may increase. This may cause high aspect ratio features to buckle, and in some circumstances may cause substrate or wafer bowing. Additionally, silicon oxide may be a relatively porous film. After processing, the substrate may be exposed to atmosphere, and oxygen from moisture may be incorporated into the film. The oxygen absorbed into the film may also cause the film to become more dense, which again may cause the compressive stress of the film to increase. Conventional technologies have been challenged to balance the shrinking and stress characteristics of produced films.

The present technology may overcome these limitations by adjusting deposition parameters and materials to produce a sealing layer about a produced film. For example, the present technology may include depositing a surface-layer of material that may produce a protective coating. This coating may both limit outgassing of the bulk film, which may limit shrinking, and may also provide a barrier for oxygen incorporation, which may densify the film and increase stress. After describing general aspects of a chamber according to embodiments of the present technology in which plasma processing operations discussed below may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

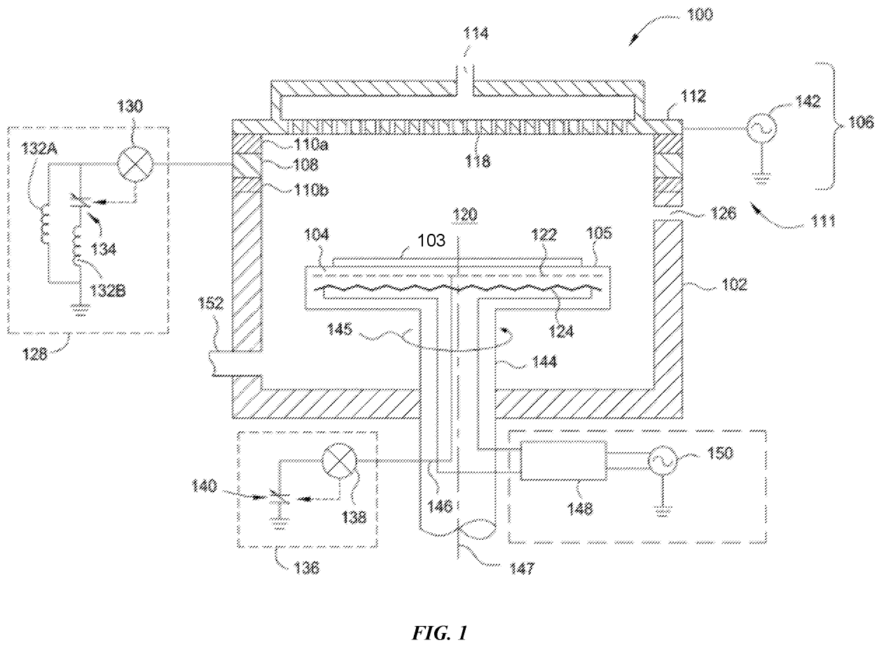

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

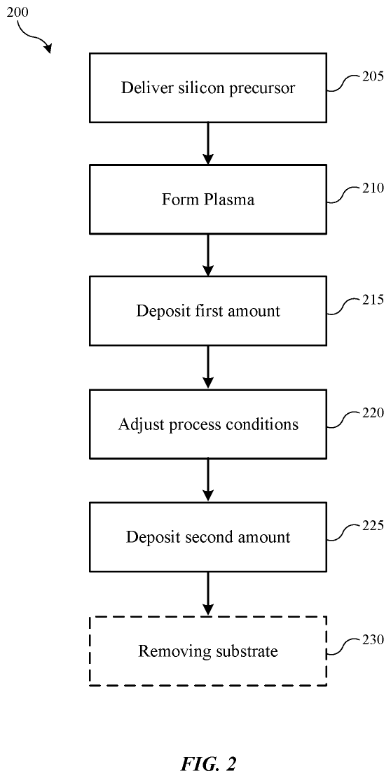

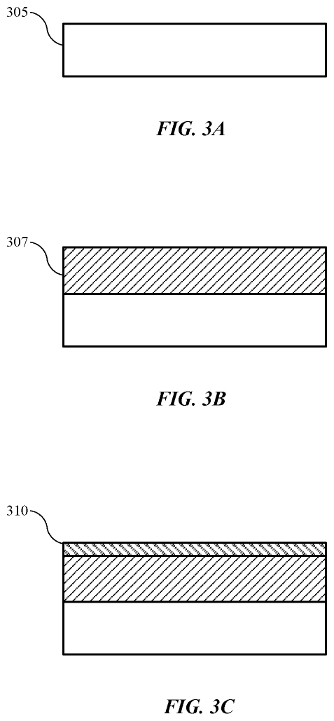

FIG. 2 shows exemplary operations in a deposition method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3C, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above. An exemplary substrate 305 is illustrated in FIG. 3A prior to initiating deposition.

The substrate 305 may be any number of materials on which materials may be deposited. The substrate may be or include silicon, germanium, dielectric materials including silicon oxide or silicon nitride, metal materials, or any number of combinations of these materials, which may be the substrate 305, or materials formed on substrate 305. In some embodiments optional treatment operations, such as a pretreatment, may be performed to prepare a surface of substrate 305 for deposition. For example, a pretreatment may be performed to provide certain ligand terminations on the surface of the substrate, and which may facilitate nucleation of a film to be deposited. Additionally, material removal may be performed, such as reduction of native oxides or etching of material, or any other operation that may prepare one or more exposed surfaces of substrate 305 for deposition.

At operation 205, one or more precursors may be delivered to the processing region of the chamber. For example, in exemplary embodiments in which a silicon-containing film may be formed, including a silicon oxide film, a silicon-containing precursor may be delivered to the processing region of the processing chamber. The silicon-containing precursor may be a silicon-and-oxygen-containing precursor in some embodiments. With the silicon-containing precursor may be delivered a carrier precursor, which may be or include an inert or noble precursor in some embodiments. Plasma enhanced deposition may be performed in some embodiments of the present technology, which may facilitate material reactions and deposition. As noted above, some embodiments of the present technology may encompass formation or deposition of silicon-and-oxygen materials, which may be characterized conventionally by a certain porosity and stress, as well as additional effects that may occur subsequent exposure to atmosphere or exposure to higher temperatures.

The precursors delivered may be used to form a plasma within the processing region of the semiconductor processing chamber at operation 210. At operation 215, a silicon-containing material 307 may be deposited on the substrate 305, such as may be illustrated in FIG. 3B. As will be described further below, the deposition may be a first amount of the silicon-containing material, which may be formed or deposited in contact with and/or overlying the substrate. The deposition of the first amount of material may occur at a first set of processing conditions, and may produce a bulk layer of material to any thickness as may be beneficial in a particular process. For example, embodiments of the present technology may be used to produce films characterized by any thickness, such as from a few nanometers or less, to several micrometers or more.

The first set of chamber conditions may include any number of process conditions or parameters for which the deposition may be performed. For example, the deposition may occur under a set of conditions that may include, as examples, chamber temperature, precursors, pressure, plasma power, precursor flow rates, deposition time, among any other number of chamber conditions, which may constitute a first set of conditions during which the first amount of material may be deposited. At operation 220, one or more of the chamber conditions may be adjusted to a second condition, which may produce a second set of chamber conditions. The adjusting may occur while continuing the deposition, for example, or the process may be halted and restarted in a discrete break while conditions are adjusted. A second amount of the silicon-containing material 310 may then be deposited at operation 225, as illustrated in FIG. 3C, and which may occur under the second set of chamber conditions. The first amount of material and the second amount of material may together produce a combination layer of material.

Any number of conditions may be maintained or adjusted during the transition between the first set of chamber conditions and the second set of chamber conditions. For example, the adjustment may include changing one or more conditions of the first set of conditions, while maintaining one or more other conditions of the first set of conditions. The conditions may be adjusted to modify one of more film properties of the materials being deposited. For example, in some embodiments the material in the first amount of material may be the same material as in the second amount of material, although one or more film properties may be adjusted. For example, the second amount of material may be characterized by increased density relative to the first amount of material in embodiments of the present technology, and may provide a protective or sealing layer about the first amount of material, such as a bulk layer of material. The second amount of material may protect against both degassing from the first amount of material, as well as ingress of oxygen if or when the substrate is exposed to atmosphere, such as when the substrate may be removed from a vacuum environment, such as in optional operation 230.

Any number of precursors may be used with the present technology with regard to the silicon-containing precursor and the carrier precursor. For example, the silicon-containing precursor may include any silicon-containing material, such as organosilanes, which may include silane, disilane, and other materials. Additional silicon-containing materials may include silicon, carbon, oxygen, or nitrogen, such as tetraethyl orthosilicate or trisilylamine, for example. In some embodiments an additional precursor may be delivered with the silicon-containing precursor, such as an oxygen-containing precursor, a nitrogen-containing precursor, or any other precursor. The carrier precursor may be or include an inert or noble gas, such as argon, helium, krypton, xenon, or other precursors that may facilitate plasma generation or process effects, such as ion bombardment, for example.

The pressure within the processing region may affect the amount of ionization and bombardment performed during the deposition, which may impact the density of the film produced. Accordingly, in some embodiments adjusting the process conditions may include changing the pressure within the processing region from a first chamber pressure to a second chamber pressure. By lowering a processing pressure, increased ion bombardment may occur by increasing the mean-free path between atoms, increasing energy and bombardment at the film surface. Increasing bombardment may produce a film characterized by increased density. Accordingly, in some embodiments a processing pressure may be reduced between the first amount of deposition and the second amount of deposition, which may produce a denser surface layer to protect against degassing and oxygen ingress as explained above.

The first set of conditions may include a pressure within the processing chamber of less than or about 50 Torr, and may be maintained at less than or about 40 Torr, less than or about 30 Torr, less than or about 20 Torr, less than or about 15 Torr, less than or about 12 Torr, less than or about 10 Torr, or less. After a sufficient amount of bulk deposition has been performed, the pressure may be reduced either step-wise or ramped down to a second chamber pressure to produce the second amount of material. For example, the second chamber pressure may be less than or about 15 Torr, and may be less than or about 12 Torr, less than or about 10 Torr, less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, or less. Regardless of the first chamber pressure, a delta chamber pressure may be produced between the first chamber pressure and the second chamber pressure, which may be greater than or about 1 Torr, and may be greater than or about 2 Torr, greater than or about 4 Torr, greater than or about 6 Torr, greater than or about 8 Torr, greater than or about 10 Torr, or more.

Method 200 may perform the deposition at one or more process temperatures, which may be above or about 200° C., and may be greater than or about 250° C., greater than or about 300° C., greater than or about 350° C., greater than or about 400° C., greater than or about 450° C., greater than or about 500° C., or higher. Additionally, the silicon-containing precursor, which may be a silicon-and-oxygen-containing precursor, may be characterized by a flow rate which may be maintained during the deposition of the first amount of the silicon-containing material and the second amount of the silicon-containing material. For example, the flow of the silicon-containing precursor may be maintained during the adjustment between the first set of conditions and the second set of conditions. In some embodiments the flow rate of the silicon-containing precursor may be increased or decreased between the first set of conditions and the second set of conditions.

Similarly, the flow rate of the carrier precursor may also be adjusted between the first amount of deposition and the second amount of deposition, for example, from a first volumetric flow rate to a second volumetric flow rate greater than the first volumetric flow rate. By increasing the amount of the carrier precursor, such as argon, for example, a partial pressure of the silicon-containing precursor may be reduced. For a silicon-and-oxygen-containing precursor, this may increase the oxygen incorporation at the film surface, and may reduce an amount of carbon and/or hydrogen incorporated in the film. The increased argon may increase bombardment at the surface, which may densify the film, and further remove incorporated carbon or hydrogen.

Accordingly, in some embodiments the second volumetric flow rate may be at least about 10% greater than the first volumetric flow rate, and may be at least about 20% greater, at least about 30% greater, at least about 40% greater, at least about 50% greater, at least about 60% greater, at least about 70% greater, at least about 80% greater, at least about 90% greater, at least about 100% greater, at least about 120% greater, at least about 140% greater, at least about 160% greater, at least about 180% greater, at least about 200% greater, or more. In some embodiments one or more conditions may be adjusted together or simultaneously during the transition, such as by reducing the pressure and increasing a volumetric flow rate of the carrier precursor simultaneously. Any number of processing parameters may be adjusted including any parameters noted, or any other relevant parameters.

As noted previously, the second amount of the silicon-containing material may be characterized by an increased density relative to the first amount of the silicon-containing material. This may also produce an increased stress characteristic in the second amount of the silicon-containing material, which may otherwise increase the compressive stress of the combination film. Accordingly, in some embodiments the second amount of the silicon-containing material may be limited in thickness. For example, the first amount of silicon-containing material may be characterized by a compressive stress of less than or about −100 MPa, and may be characterized by a compressive stress of less than or about −90 MPa, less than or about −80 MPa, less than or about −70 MPa, less than or about −60 MPa, less than or about −50 MPa, less than or about −40 MPa, or less. The second amount of the silicon-containing material may be characterized by a compressive stress of greater than or about −100 MPa, and may be characterized by a film compressive stress of greater than or about −120 MPa, greater than or about −140 MPa, greater than or about −160 MPa, greater than or about −180 MPa, greater than or about −200 MPa, greater than or about −220 MPa, greater than or about −240 MPa, greater than or about −260 MPa, greater than or about −280 MPa, greater than or about −300 MPa, or higher.

If the second amount of the silicon-containing material may be sufficient thickness, the overall compressive stress of the combination layer may cause any of the issues described previously. Accordingly, in some embodiments, the second amount of the silicon-containing material may be maintained at a thickness of less than or about 150 nm, and may be maintained at a thickness of less than or about 130 nm, less than or about 110 nm, less than or about 100 nm, less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, less than or about 1 nm, or less.

Additionally, to ensure control of degassing at increased processing temperatures, as well as to limit ingress of atmospheric moisture, the second amount of the silicon-containing material may be maintained at a thickness of greater than or about 0.5 nm, and may be maintained at a thickness of greater than or about 1 nm, greater than or about 5 nm, greater than or about 10 nm, greater than or about 15 nm, greater than or about 20 nm, greater than or about 25 nm, greater than or about 30 nm, or greater. The minimum thickness to provide the associated benefits may be at least partially related to the density of the second amount of material. For example, the denser the material formed, the thinner may be the layer. However, the compressive stress may also increase with more dense layers, and so the density, or stress, and thickness of the second amount of material may be controlled to provide the associated benefits, while limiting the affects from increased compressive stress.

Depending on the processing conditions, the deposition of the first amount of material may be performed for a first amount of time, and the deposition of the second amount of material may be performed for a second amount of time less than the first amount of time. For example, in some embodiments, and to limit a thickness of the second amount of material, the second amount of time may be less than or about 30 seconds, and may be less than or about 25 seconds, less than or about 20 seconds, less than or about 15 seconds, less than or about 10 seconds, less than or about 5 seconds, or less.

By producing a relatively thin layer of denser material overlying a bulk material, film shrinking may be limited or substantially prevented, while maintaining a desired stress characteristic of the combined film. For example, and depending on the thickness of the first amount of material and the second amount material, the combination layer may be characterized by an overall compressive stress of less than or about −70 MPa, and may be characterized by an overall compressive stress of less than or about −65 MPa, less than or about −60 MPa, less than or about −55 MPa, or less. Additionally, film shrinkage may be reduced by greater than or about 10% compared to a film without a sealing layer during subsequent processing or atmospheric exposure, and may be reduced by greater than or about 15%, greater than or about 20%, greater than or about 25%, greater than or about 30%, greater than or about 35%, greater than or about 40%, greater than or about 45%, greater than or about 50%, greater than or about 55%, greater than or about 60%, or more.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A deposition method comprising:
delivering a silicon-containing precursor and a carrier precursor to a processing region of a semiconductor processing chamber;
forming a plasma of the silicon-containing precursor and the carrier precursor within the processing region of the semiconductor processing chamber;
depositing a first amount of a silicon-containing material on a substrate disposed within the processing region of the semiconductor processing chamber, wherein the depositing occurs at a first chamber pressure;
adjusting the first chamber pressure to a second chamber pressure less than the first chamber pressure; and
depositing a second amount of the silicon-containing material on the first amount of the silicon-containing material.

2. The deposition method of claim 1, wherein the silicon-containing precursor is a silicon-and-oxygen-containing precursor, and wherein the silicon-containing material comprises silicon oxide.

3. The deposition method of claim 1, wherein the first chamber pressure is less than or about 20 Torr, and wherein the second chamber pressure is less than or about 10 Torr.

4. The deposition method of claim 1, wherein a substrate temperature is maintained above or about 300° C. while depositing the first amount of the silicon-containing material and the second amount of the silicon-containing material.

5. The deposition method of claim 1, wherein the carrier precursor comprises argon.

6. The deposition method of claim 1, further comprising:
increasing a volumetric flow rate of the carrier precursor while adjusting the first chamber pressure to the second chamber pressure.

7. The deposition method of claim 1, wherein the second amount of the silicon-containing material is characterized by a greater density than the first amount of the silicon-containing material.

8. The deposition method of claim 1, wherein the silicon-containing precursor comprises tetraethyl orthosilicate.

9. The deposition method of claim 1, wherein the second amount of the silicon-containing material is characterized by a thickness of less than or about 100 nm.

10. A deposition method comprising:
delivering a silicon-containing precursor and a carrier precursor to a processing region of a semiconductor processing chamber;
forming a plasma of the silicon-containing precursor and the carrier precursor within the processing region of the semiconductor processing chamber;
depositing a first amount of a silicon-containing material on a substrate disposed within the processing region of the semiconductor processing chamber, wherein the depositing occurs at a first chamber pressure;
adjusting the carrier precursor from a first volumetric flow rate to a second volumetric flow rate greater than the first volumetric flow rate; and
depositing a second amount of the silicon-containing material on the first amount of the silicon-containing material.

11. The deposition method of claim 10, wherein the silicon-containing precursor is a silicon-and-oxygen-containing precursor, and wherein the silicon-containing material comprises silicon oxide.

12. The deposition method of claim 10, wherein the second volumetric flow rate is more than 50% greater than the first volumetric flow rate.

13. The deposition method of claim 10, further comprising:
adjusting the first chamber pressure to a second chamber pressure less than the first chamber pressure while adjusting the carrier precursor from the first volumetric flow rate to the second volumetric flow rate.

14. The deposition method of claim 13, wherein the first chamber pressure is less than or about 15 Torr, and wherein the second chamber pressure is less than or about 7 Torr.

15. The deposition method of claim 10, wherein the second amount of the silicon-containing material is characterized by a thickness of less than or about 100 nm.

16. The deposition method of claim 15, wherein the second amount of the silicon-containing material is characterized by a compressive stress greater than or about a compressive stress associated with the first amount of the silicon-containing material.

17. A deposition method comprising:
delivering a silicon-and-oxygen-containing precursor and a carrier precursor to a processing region of a semiconductor processing chamber;
forming a plasma of the silicon-and-oxygen-containing precursor and the carrier precursor within the processing region of the semiconductor processing chamber;
depositing a first amount of a silicon-and-oxygen-containing material on a substrate disposed within the processing region of the semiconductor processing chamber, wherein the depositing occurs at a first chamber pressure;
adjusting the first chamber pressure to a second chamber pressure less than the first chamber pressure;
while adjusting chamber pressure, increasing a volumetric flow rate of the carrier precursor; and
depositing a second amount of the silicon-and-oxygen-containing material on the first amount of the silicon-and-oxygen-containing material.

18. The deposition method of claim 17, wherein the first chamber pressure is less than or about 20 Torr, and wherein the second chamber pressure is less than or about 10 Torr.

19. The deposition method of claim 18, wherein the silicon-and-oxygen-containing precursor comprises tetraethyl orthosilicate, and wherein the carrier precursor comprises argon.

20. The deposition method claim 17, wherein the first amount of the silicon-and-oxygen-containing material is deposited over a first period of time, and wherein the second amount of the silicon-and-oxygen-containing material is deposited over a second period of time less than the first period of time.
